(19) United States
(12) Patent Application Publication
(10) Pub. No.: US 2013/0048046 A1
(43) Pub. Date: Feb. 28, 2013

(54) PHOTOVOLTAIC MODULE

(71) Applicants: Raymond Domsic, Gross Iie, MI (US); Jusin C. Gosnell, Perrysburg, OH (US)

(72) Inventors: Raymond Domsic, Gross Iie, MI (US); Jusin C. Gosnell, Perrysburg, OH (US)

(21) Appl. No.: 13/596,474

(22) Filed: Aug. 28, 2012

Related U.S. Application Data
(60) Provisional application No. 61/528,874, filed on Aug. 30, 2011.

(51) Int. Cl. H01R 43/00; B32B 3/10; H01L 31/042

(52) U.S. Cl. 136/244; 29/877; 428/138

(57) ABSTRACT

An adhesive element can be used to attach a conductor interface to a photovoltaic module. The adhesive element provides multiple points of support for conductors connected within the conductor interface and improves sealing against moisture intrusion.

This application claims priority to U.S. Provisional Application Ser. No. 61/528,874, which was filed on Aug. 30, 2011, and is herein incorporated by reference in its entirety.

### TECHNICAL FIELD

The disclosed embodiments relate to adhesives for photovoltaic devices and methods for manufacturing photovoltaic devices.

### BACKGROUND

Photovoltaic (PV) modules are becoming increasing popular for providing renewable energy. FIGS. 1 and 2 show a top perspective view and a bottom perspective view, respectively, of a conventional photovoltaic module 10. Module 10 is oriented to receive sunlight through a superstrate layer 110. The sunlight is then converted to electricity within the module using semiconductors. To facilitate this conversion process, module 10 can include a plurality of PV cells formed on superstrate layer 110. The cells can be connected in series, parallel, or a combination thereof depending on the desired electrical output from module 10. Brackets 115 connected to module 10 (for example, to peripheral edges of superstrate layer 110 and a back plate 140) may be used to fix module 10 to a support structure.

Protruding from the back plate 140 of module 10 are external conductors 120, 125, which facilitate connection and transmission of the electrical current generated by module 10 to other electrical devices or loads. External conductors 120, 125 may be any appropriate wires or cables known in the art, and may include insulating jacket(s) surrounding their conductive core. External conductors 120, 125 may include industry-compliant connectors 130, 135 for ease of installation and interconnection with other elements in the photovoltaic system. As shown in FIG. 2, a conductor interface 150 (for example, a junction box) can be installed adjacent to back plate 140 of module 10, which has an opening to permit electrical connection of the PV cells within a module. Conductor interface 150 is provided over the opening and houses the interconnections of internal conductors that are connected to an internal bussing system of module 10 (such as a conductive material electrically connected within module 10) with external conductors 120, 125.

FIG. 3 shows a cross-sectional view of one example of a module 10 taken along section A-A (FIG. 1). As shown in FIG. 3, each PV cell within module 10 can include a plurality of layers. Superstrate layer 110 serves as a durable exterior layer and also permits incident light to permeate the module 10. The plurality of layers can include a front contact layer 215 formed adjacent to superstrate layer 110, which may include a barrier layer to reduce diffusion of sodium ions or other contaminants from superstrate layer 110 to other layers of the module, a conductive and highly transparent conductive oxide (TCO) layer, and a buffer layer for isolating the TCO layer electrically and chemically from adjacent layers. Front contact layer 215 may serve as a first node for an internal bussing system of module 10. A semiconductor window layer 220 can be formed adjacent to front contact 215, serving as a transparent pathway to a semiconductor absorber layer 225 formed adjacent to semiconductor window layer 220. A p-n junction may be formed where semiconductor absorber layer 225 contacts semiconductor window layer 220. A back contact layer 230 formed adjacent to absorber layer 225 can serve as a second node for the internal bussing system of module 10.

An interlayer 235 may be formed adjacent to back contact layer 230, and may serve as a moisture barrier to module 10 and an electrical insulator between the plurality of layers of module 10 and back plate 140, as well as a bonding agent that bonds back plate 140 to module 10. An insulating seal 245 may be provided between superstrate layer 110 and back plate 140, in an area between the edge of layers 215-235 and the peripheral edge of superstrate 110 and back plate 140. Insulating seal 245 may be light transmissive and formed of a polymer material that is selected from a group consisting of polycarbonate, acrylic, silicone, and polyurethane.

To enclose module 10, back plate 140 may be provided adjacent to interlayer 235 and/or insulating seal 245. Back plate 140 together with superstrate 110, insulating seal 245, and conductor interface 150 protects the plurality of layers from moisture intrusion, physical damage, or environmental hazards. Back plate 140 can be composed of any suitable protective material, such as borosilicate glass, float glass, soda lime glass, carbon fiber, or polycarbonate.

A p-n junction is formed where semiconductor absorber layer 225 abuts semiconductor window layer 220. When photovoltaic module 10 is exposed to sunlight, photons may be absorbed within the p-n junction region. As a result, photo-generated electron-hole pairs may be created. Movement of the electron-hole pairs may be promoted by a built-in electric field, thereby producing an electrical current on an internal bussing system (not shown) in module 10, for instance, to internal conductors that are connected to front contact layer 215 and back contact layer 230. This electrical current is output from module 10 via external conductors 120, 125 (FIG. 2).

Photovoltaic modules are commonly installed outdoors to allow for direct sunlight exposure. Outdoor installation exposes the modules to moisture in the form of precipitation and humidity. It is desirable to manufacture a module having a conductor interface that is thoroughly sealed against moisture ingress.

### BRIEF DESCRIPTION OF THE DRAWINGS

FIG. 1 is a top perspective view of an example photovoltaic module.

FIG. 2 is a bottom perspective view of the photovoltaic module of FIG. 1.

FIG. 3 is a cross-sectional view of FIG. 1 taken along section A-A.

FIG. 4 is an exploded bottom view of a photovoltaic module without external conductors.

FIG. 5 is an exploded bottom view of a photovoltaic module.

FIG. 6 is a partially exploded bottom view of a photovoltaic module.

FIG. 7 is a bottom view of a photovoltaic module.

FIG. 8 is a roll of tape.

FIG. 9 is a length of tape containing a series of adhesive elements.

FIG. 10 is a length of tape with an adhesive element extracted.

FIG. 11 is a cross-sectional side view of a conductor interface.

FIG. 12 is a cross-sectional side view of a conductor interface filled with potting material.

FIG. 13 is a top perspective view of an adhesive element.

FIG. 14 is a top perspective view of an adhesive element.

FIG. 15 is a top perspective view of an adhesive element.

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein.

Conventional photovoltaic modules may include an adhesive element that is used to bond a module 10 to a conductor interface 150 (FIG. 2). Conventional adhesive elements used for this purpose, however, typically include openings designed only to accommodate the connected portions (e.g., the ends) of first and second external conductors 120, 125 (FIG. 2) to corresponding internal conductors within the module.

The use of such conventional adhesive elements may prevent a potting material used to fill the interior of conductor interface 150 from fully encompassing the circumference of external conductors 120, 125. Potting material is typically used to fill the conductor interface 150 after the conductor interface 150 has been bonded to module 10 and the external conductors 120, 125 electrically connected to the internal bussing system of module 10. The potting material maintains the external conductors in place, and provides additional moisture resistance. Because external conductors 120, 125 are positioned directly against the conventional adhesive element along their length, however, the potting material cannot permeate between external conductors 120, 125 and the conventional adhesive element. As a result, either during manufacture or after the passage of time, a small void can form in the potting material along the length of one or more of external conductors 120, 125; this void can serve as a channel for water to enter conductor interface 150. Moisture can accumulate on the jacket of external conductors 120, 125 and travel along the outer surface of the wire jacket and into conductor interface 150. This situation could be further aggravated by insufficient bonding between the potting material and the conventional adhesive element. For instance, over time the potting material could peel away from the conventional adhesive element.

Embodiments described herein include an adhesive element for bonding a conductor interface to a back plate of a photovoltaic module. The adhesive element can include openings that are arranged such that each adhesive element provides first and second points of support for an external conductor connected within the conductor interface to electrical conductors within a photovoltaic module. In described embodiments, the openings in the adhesive element may be arranged to align with one or more conductors in the conductor interface, such that when the inner volume of the conductor interface is filled with a potting material, the openings allow the potting material to encase the conductors. Methods of manufacturing a photovoltaic module are also described.

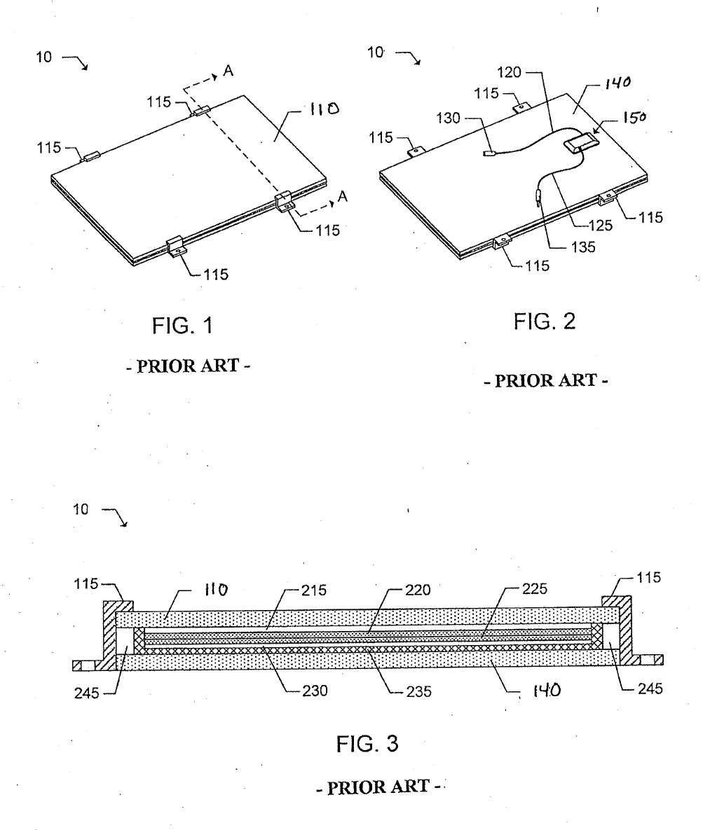

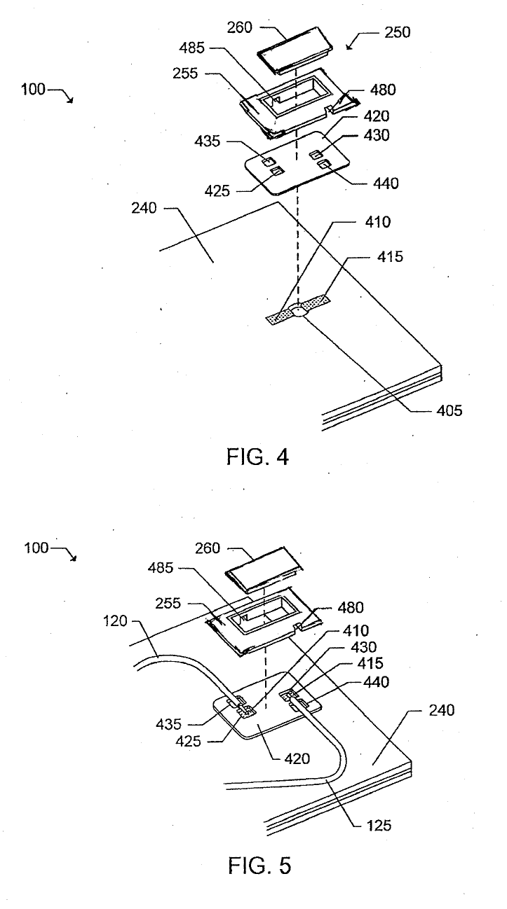

Referring to FIG. 4, an exploded bottom view of a photovoltaic module 100 is shown. Module 100 includes a back plate 240, which may be similar to back plate 140 described above in connection with FIGS. 1-3, and a conductor interface 250. In one embodiment, conductor interface 250 is a junction box including a base portion 255 and a cover portion 260 that are configured to interconnect, such as through a clipping mechanism. Base portion 255 includes access holes 480, 485 through which external conductors 120, 125 (FIG. 5) can be inserted. In another embodiment, conductor interface 250 is a junction box or other appropriate conductor interface that is provided as a single element.

Conductor interface 250 can be installed over a back plate opening 405 of module 100. First and second internal conductors 410, 415 of module 100 are exposed by back plate opening 405, and may extend from an internal portion of module 100 to an external portion of module 100 through back plate opening 405. First and second internal conductors 410, 415 may be part of an internal bussing system within module 100. For example, first internal conductor 410 may be connected to the front contact 215 of at least one cell within module, and second internal conductor 415 may be connected to back contact layer 235 of at least one cell within module 100. Once extended through back plate opening 405, first and second internal conductors 410, 415 may then be folded back against opposing sides of back plate opening 405, which can prevent shorting between conductors 410, 415.

As shown in FIG. 5, first and second external conductors 120, 125 are electrically connected to first and second internal conductors 410, 415, respectively, in module 100 and pass through conductor interface 250. External conductors 120, 125 facilitate connection and transmission of the electrical current generated by module 100 to other electrical devices or loads. In one example, external conductors 120, 125 may be any appropriate wires or cables known in the art, and may include insulating jacket(s) surrounding their conductive core. External conductors 120, 125 may include industry-compliant connectors 130, 135 for ease of installation and interconnection with other elements in the photovoltaic system. Within conductor interface 250, external conductors 120, 125 can be electrically connected to internal conductors 410, 415 through any suitable technique. For instance, a first external conductor 120 can be soldered to first internal conductor 410. Likewise, a second external conductor 125 can be soldered to second internal conductor 415. First and second external conductors 120, 125 can also be connected to first and second internal conductors 410, 415, respectively, using other known techniques.

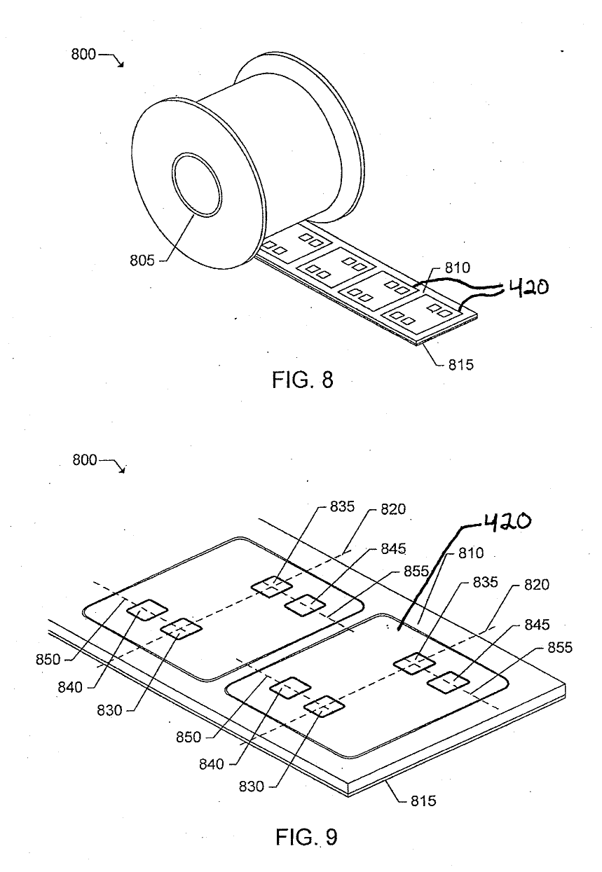

As shown in FIGS. 4-5, an adhesive element 420 is used to attach conductor interface 250 to module 100. Adhesive element 420 can be composed of any suitable adhesive material or sealant. For example, as discussed further below with regard to FIGS. 8-10, adhesive element 420 can be formed as a section of a roll of double side adhesive tape 800, such as a foam tape that includes a foam layer coated on both sides with an adhesive coating, or a non-foam tape. Adhesive element 420 may be formed, for example, on any foam tape or adhesive foam layer having suitable bond strength and erosive qualities.

After first and second internal conductors 410, 415 are folded against back plate 240, adhesive element 420 can be installed over the first and second internal conductors 410, 415. Adhesive element 420 can cover and seal back plate opening 405. Adhesive element 420 can also cover a portion of the first and second internal conductors 410, 415, immobilizing first and second internal conductors 410, 415 and preventing them from contacting each other and shorting module 100.

As shown in FIG. 5, adhesive element 420 includes first and second openings 425, 430 that are located on adhesive element 420 in a manner to provide access to first and second internal conductors 410, 415, respectively. First and second openings 425, 430 are arranged to allow electrical connections to be made between first and second internal conductors 410, 415 and first and second external conductors 120, 125.

Adhesive element 420 also includes third and fourth openings 435, 440. Third and fourth openings 435, 440 correspond to installation locations for first and second external conductors 120, 125, respectively, with third opening 435 positioned near first opening 425 and located beneath the installation location of first external conductor 120, and fourth opening 440 positioned near second opening 430 and located beneath the installation location of second external conductor 125.

Referring to FIGS. 11 and 12, once internal conductors 410, 415 have been electrically connected to external conductors 120, 125 and base portion 255 of conductor interface 250 has been adhered to back plate 240, a potting material 1205 can be added to the interior of conductor interface 250. In one example, potting material 1205 can be injected into conductor interface 250 and may fill, or nearly fill, the interior of conductor interface 250. FIG. 11 shows a cross-sectional view of conductor interface 250 prior to being filled with potting material 1205, and FIG. 12 shows a cross-sectional view of conductor interface 250 after potting material 1205 has been added.

Potting material 1205 provides a moisture barrier that prevents moisture from reaching interior surfaces of module 100 that are susceptible to corrosion. Further, potting material 1205 serves as an insulating material and prevents short circuiting between first and second internal conductors 410, 415. Furthermore, potting material 1205 provides structural support to the components housed within conductor interface 250. For example, potting material 1205 may envelop external conductors 120, 125 and prevent them from coming loose or from being pulled out of conductor interface 250.

Unlike conventional adhesive elements that may be used to bond a module to a conductor interface, which typically include openings designed only to accommodate the connected portions (e.g., the ends) of first and second external conductors 120, 125 and corresponding first and second internal conductors 410, 415, adhesive element 420 provides spaces to allow potting material 1205 to fully encase the outer circumference of external conductors 120, 125. By way of contrast, a conventional adhesive element may include only openings 425 and 430 in adhesive 420 of FIG. 5, to accommodate the end portions of external conductors 120, 125 and internal conductors 410, 415.

In adhesive element 420, third and fourth openings 435, 440 provide a space to allow potting material 1205 to fully encase the circumference of external conductors 120, 125. As a result, water may be prevented from following the wires 120, 125 into conductor interface 250. In addition, third and fourth openings 435, 440 allow potting material 1205 to bond with back plate 240 at the installation location of first and second external conductors 120, 125, which can form a superior bond to that formed between potting material 1205 and adhesive element 420. For example, if back plate 240 is constructed from glass, the bond strength between potting material 1205 and the glass can be very high. This added bond strength can enable external conductors 120, 125 to withstand higher destructive forces without disconnecting from conductor interface 250. This can prevent unintended disconnections from occurring.

Third and fourth openings 435, 440 also allow adhesive element 420 to provide additional points of support for external conductors 120, 125. Conventional adhesive elements with only first and second openings (e.g., openings 425, 430) may provide only a single point of support for external conductors 120, 125 (i.e., the portion of the adhesive element underlying external conductors 120, 125). This single point of support can act as a fulcrum and cause unwanted stress on the soldered connection when the respective external conductor 120, 125 is disturbed. This unwanted stress can also cause the respective external conductor 120, 125 to separate from the adhesive element, which promotes water intrusion. By providing two points of support along each of external conductors 120, 125, the stability of each external conductor 120, 125 is improved.

Adhesive element 420 can have any suitable outer dimensions. In one example, for a PV module 100 having overall dimensions of 60 cm by 120 cm and a power output of about 80 W, adhesive element 420 can have a width between 20 and 100 mm and a length of between 40 and 120 mm. More preferably, adhesive element 420 can have a width between 40 and 80 mm and a length between 60 and 100 mm. The midpoints of first and second openings 425, 430 can be spaced between 30 and 80 mm apart and can be located along a lengthwise centerline 820 of adhesive element 420. More preferably, the midpoints of first and second openings 425, 430 can be spaced about 45 mm apart.

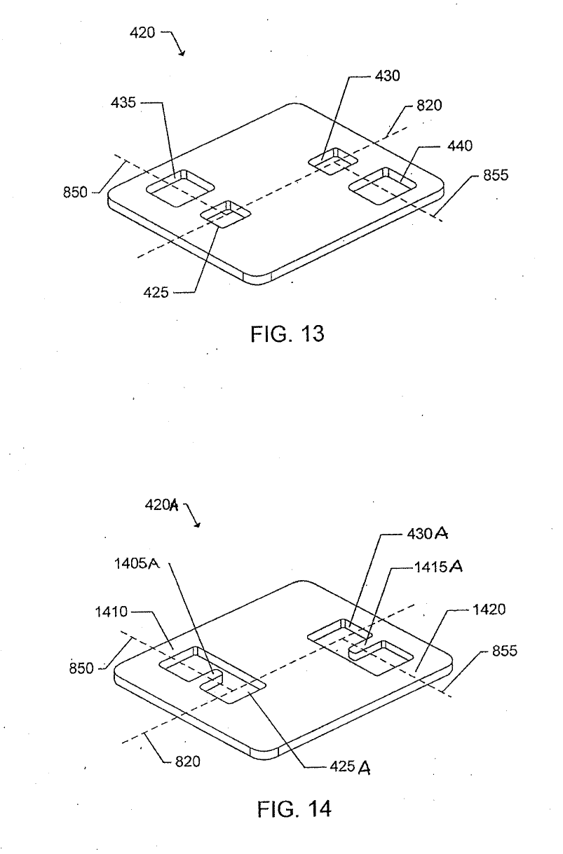

First, second, third, and fourth openings 425, 430, 435, 440 in adhesive element 420 may each have a width of between 5 and 20 mm and a length between 5 and 20 mm, with areas between about 0.25 cm² and 4 cm². In one embodiment, first, second, third, and fourth openings 425, 430, 435, 440 may each have approximately the same dimensions. In other embodiments, first, second, third, and fourth openings 425, 430, 435, 440 can have different dimensions and/or different shapes, such as, for example, rectangular, oval, or round. For example, as shown in FIG. 13, third and fourth openings 435, 440 can be larger than first and second openings 425, 430. Alternately, first and second openings 425, 430 can be larger than third and fourth openings 435, 440.

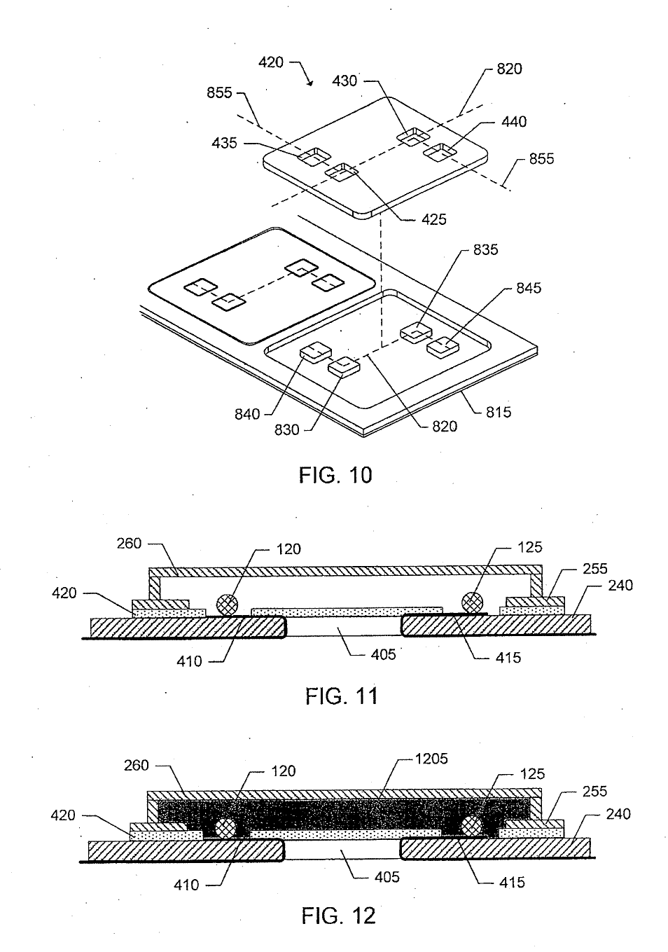

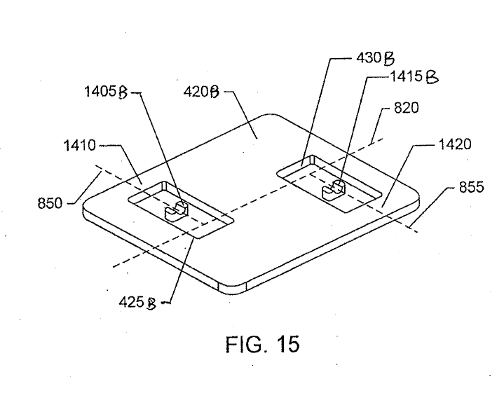

Adhesive element 420 can be provided in a prefabricated manner. As shown in FIGS. 8-10, multiple prefabricated adhesive elements 420 can be provided on a roll of tape 800. Providing the prefabricated adhesive elements 420 on a roll of tape 800 facilitates distribution, storage, and dispensing of the foam tape. Tape 800 may be foam tape including a foam layer 810 with an adhesive coating on both sides. A non-stick backing layer 815 can be attached to one or both sides of foam layer 810. A punching process, or other suitable process, can be used to form a series of perforations in sections along the length of the foam layer 810, including perforations forming the openings described above with regard to FIG. 13 or those described further below with regard to FIGS. 14 and 15, and perforations between each adhesive element 420A, 420B to allow an individual adhesive element 420 to be readily separated from the backing layer 815 (FIG. 10) and used to attach a conductor interface 250 to a back plate 240 of a photovoltaic module 100 (FIG. 7).

As shown in FIGS. 8 and 10, in one embodiment for providing a roll of prefabricated adhesive elements, a punching process is performed to form the perforations of adhesive elements 420 in the foam layer 810. During the punching process, a die cuts through foam layer 810, but does not cut through backing layer 815. By doing so, backing layer 815 provides support for the series of perforations and allows them to be wrapped around a core 805.

As shown in FIGS. 9 and 10, first and second perforations 830, 835 are formed along a lengthwise centerline 820 of each adhesive element 420, in order to produce first opening 425 and second opening 430 (FIG. 13). Third and fourth perforations 840, 845 are formed adjacent to each first and second perforation, respectively, to produce third and fourth openings 435, 440. As discussed above, third and fourth openings 435, 440 provide sealing and retention capabilities for first and second external conductors 120, 125 (FIG. 12). Third perforation 840 is formed in a location to correspond to the eventual installation location of first wire 120. In particular, third perforation 840 may be positioned corresponding to the eventual centerline 850 of first wire 120. Likewise, fourth perforation 845 may formed in a location to correspond to the eventual installation location of second wire 125. In particular, fourth perforation 845 may be positioned corresponding to the eventual centerline 855 of second wire 125.

In a process for manufacturing photovoltaic module 100, roll 800 of foam tape (FIG. 8) can be employed on an assembly line to provide a respective adhesive element 420 for the assembly of each of multiple photovoltaic modules 100. In one example, a sub-assembly of a partially completed photovoltaic module enters a work station; an adhesive element 420 from roll 800 is applied between conductor interface 250 and back plate 240.

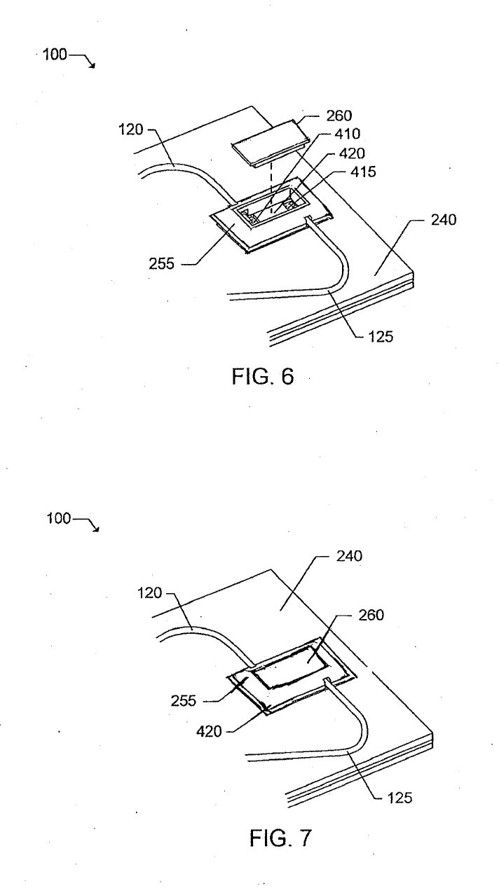

The relative order of operations during the process for manufacturing photovoltaic module 100 can follow one of several methods. In one embodiment, prior to providing first and second external conductors 120, 125, adhesive element 420 is attached to back plate 240 proximate back plate opening 405, as shown in FIGS. 4 and 5. First and second external conductors 120, 125 are respectively soldered to first and second internal conductors 410, 415. As shown in FIG. 6, base portion 255 is then assembled over external conductors 120, 125 and adhesive element 420. Potting material 1205 (FIG. 12) is then added to the interior volume of conductor interface 250, and cover portion 260 is attached to base portion 255, as shown in FIG. 7.

In another embodiment, a sub-assembly of base portion 255 and adhesive element 420 can first be formed by applying adhesive element 420 to the bottom surface of base portion 255, and this sub-assembly is then attached to back plate 240 adjacent to back plate opening 405. External conductors 120, 125 are then inserted into conductor interface 250 through access holes 480, 485 in base portion 255, and electrically connected to internal conductors 410, 415 (for example, using a soldering iron through the opening in the top surface of base portion 255 of conductor interface 250 or ultra-sonic welding), to form the sub-assembly shown in FIG. 6. Once the soldered connections have been formed, potting material 1205 (FIG. 12) can be added to the interior volume of conductor interface 250 before attaching cover portion 260 to base portion 255. In another embodiment, cover portion 260 and/or base portion 255 can include an injection point (such as a small hole) that allows potting material 1205 to be injected after cover portion 260 has been attached to conductor interface 250.

The dimensions and areas listed above are provided only as examples. The actual dimensions can differ from these values while still providing similar functionality. In particular, when larger or smaller modules are manufactured, the size of adhesive element 420 can be adjusted to accommodate the size of the conductor interface. Similarly, when the number of internal conductors 410, 415 is greater than two, adhesive element 420 can have more openings of different or the same dimensions to accommodate additional connection points. For example, if module 100 is divided into several sub-modules and includes two or more internal conductors for each sub-module, additional openings may be added to adhesive element 420 to accommodate electrical connections between corresponding internal and external conductors. In particular, for each internal conductor (e.g., 410) and corresponding external conductor (e.g., 120), adhesive element 420 can include two openings, with the first opening (e.g., 425) accommodating the electrical connection between the internal conductor 410 and the external conductor 120, and the second opening (e.g., 435) providing access for potting material 1205 to contact back plate 240 and encircle the external conductor 120.

In other embodiments, adhesive element 420 may have less than four openings while still permitting potting material 1205 to encompass external conductors 120, 125 and providing two points of support for each external conductor 120, 125. For example, FIG. 14 shows an adhesive element 420A with lengthwise centerline 820, a first opening 425A, and a second opening 430A, where a portion 1405A of the adhesive element 420A extends into first opening 425A, and another portion 1415A of adhesive element 420A extends into second opening 430A. First opening 425A extends along a width of adhesive element 420A corresponding to the eventual centerline 850 of first external conductor 120 (FIG. 5). Second opening 430A extends along a width of adhesive element 420A corresponding to the eventual centerline 855 of second external conductor 125. Thus, first opening 425A and second opening 430A provide an area under first and second external conductors to permit potting material 1205 (FIG. 12) to encompass external conductors 120, 125.

In the embodiment shown in FIG. 14, the portion 1405A of adhesive element 420A extending into first opening 425A provides a first point of support for first external conductor 120, and the portion 1410A of adhesive element 420A between first opening 425A and an outer periphery of adhesive element 420A provides a second point of support for first external conductor 120. Similarly, the portion of adhesive element 420A extending into second opening 430A provides a first point of support for second external conductor 125, and the portion 1420A of adhesive element 420A between second opening 430A and an outer periphery of adhesive element 420A provides a second point of support for second external conductor 125.

FIG. 15 shows another embodiment of an adhesive element 420B. Adhesive element 420B with lengthwise centerline 820 includes a first opening 425B and a second opening 430B, where a separate supporting element 1405B, which may be, for example, formed from a detached portion of the adhesive element 420B, is located in first opening 425B, and another separate supporting element 1415B, which may also be formed, for example, from a detached portion of adhesive element 420B, is located in second opening 430B. It should be understood that, because adhesive element 420B may be provided in a prefabricated fashion (as discussed above with regard to FIGS. 8-10), separate supporting elements 1405B, 1415B may be formed through perforations in foam layer 810 and maintained in place until adhesive element 420B is applied. In adhesive element 420B, first opening 425B extends along a width of adhesive element 420B corresponding to the eventual centerline 850 of first wire 120 (FIG. 5), and second opening 430B extends along a width of adhesive element 420B corresponding to the eventual centerline 855 of second wire 125. Thus, first opening 425B and second opening 430B provide an area under first and second external conductors to permit potting material 1205 (FIG. 12) to encompass external conductors 120, 125.

In the embodiment shown in FIG. 15, the separate supporting element 1405B of adhesive element 420B located in first opening 425B provides a first point of support for first external conductor 120, and the portion 1410B of adhesive element 420B between first opening 425B and an outer periphery of adhesive element 420B provides a second point of support for first external conductor 120. Similarly, the separate supporting element 1415B of adhesive element 420B located in second opening 430B provides a first point of support for second external conductor 125, and the portion 1420B of adhesive element 420B between second opening 430B and an outer periphery of adhesive element 420B provides a second point of support for second external conductor 125.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. It should also be understood that the appended drawings are not necessarily to scale, presenting a somewhat simplified representation of various features and basic principles of the invention.

What is claimed as new and desired to be protected by Letters Patent of the United States is:

1. A photovoltaic module comprising:
a back plate having a back plate opening;
a conductor interface adjacent the back plate and covering the back plate opening;
a conductor for providing an electrical connection between the module and an external electrical device, the conductor being electrically connected to the module through the back plate opening; and
an adhesive element for fastening the conductor interface to the back plate and for providing at least two points of support for the conductor.

2. The photovoltaic module of claim 1, further comprising:
a second conductor for providing an electrical connection between the module and an external electrical device, the second conductor being electrically connected to the module through the back plate opening,
wherein the adhesive element provides at least two points of support for the second conductor.

3. The photovoltaic module of claim 1, further comprising a first internal conductor electrically connected to an interior of the module and extending to an exterior of the module through the back plate opening,
wherein the conductor comprises an external conductor extending into the conductor interface and electrically connected to the first internal conductor.

4. The photovoltaic module of claim 3, wherein the adhesive further comprises a first opening and a second opening in the adhesive element, wherein a first point of support for the external conductor is provided by a portion of the adhesive element formed between the first opening and the second opening, and a second point of support for the external conductor is provided by a portion of the adhesive element formed between the second opening and an outer perimeter of the adhesive element.

5. The photovoltaic module of claim 2, further comprising first and second internal conductors electrically connected to an interior of the module and extending to an exterior of the module through the back plate opening,
wherein the conductor comprises a first external conductor extending into the conductor interface and electrically connected to the first internal conductor, and the second conductor comprises a second external conductor extending into the conductor interface and electrically connected to the second internal conductor.

6. The photovoltaic module of claim 5, wherein the adhesive comprises:
a first opening and a second opening in the adhesive element, wherein a first point of support for the first external conductor is provided by a portion of the adhesive element formed between the first opening and the second opening, and a second point of support for the first conductor is provided by a portion of the adhesive element formed between the second opening and an outer perimeter of the adhesive element; and
a third opening and a fourth opening in the adhesive element, wherein a first point of support for the second external conductor is provided by a portion of the adhesive element formed between the third opening and the fourth opening, and a fourth point of support for the second external conductor is provided by a portion of the adhesive element formed between the third opening and an outer perimeter of the adhesive element.

7. The photovoltaic module of claim 3, the adhesive further comprising a first opening in the adhesive element, wherein a first point of support for the external conductor is provided by a portion of the adhesive element extending into the first opening and a second point of support for the external conductor is provided by a portion of the adhesive element formed between the first opening and an outer perimeter of the adhesive element.

8. The photovoltaic module of claim 5, wherein the adhesive comprises:
a first opening in the adhesive element, wherein a first point of support for the first external conductor is provided by a portion of the adhesive element extending into the first opening and a second point of support for the external conductor is provided by a portion of the adhesive element formed between the first opening and an outer perimeter of the adhesive element; and
a second opening in the adhesive element, wherein a first point of support for the second external conductor is provided by a portion of the adhesive element extending into the second opening and a second point of support for the second external conductor is provided by a portion of the adhesive element formed between the second opening and an outer perimeter of the adhesive element.

9. The photovoltaic module of claim 3, the adhesive further comprising a first opening in the adhesive element, wherein a first point of support for the external conductor is provided by a separate supporting element within the first opening, and a second point of support for the external conductor is provided by a portion of the adhesive element formed between the first opening and an outer perimeter of the adhesive element.

10. The photovoltaic module of claim 5, wherein the adhesive comprises:
a first opening in the adhesive element, wherein a first point of support for the first external conductor is provided by a separate supporting element within the first opening, and a second point of support for the second external conductor is provided by a portion of the adhesive element formed between the first opening and an outer perimeter of the adhesive element; and
a second opening in the adhesive element, wherein a first point of support for the second external conductor is provided by a separate supporting element within the second opening, and a second point of support for the second external conductor is provided by a portion of the adhesive element formed between the second opening and an outer perimeter of the adhesive element.

11. The photovoltaic module of claim 1, wherein an inner volume of the conductor interface comprises potting material, and wherein the at least one adhesive element is configured to allow the potting material to encompass the conductor.

12. The photovoltaic module of claim 1, wherein the adhesive element comprises an adhesive layer.

13. The photovoltaic module of claim 1, the back plate comprising at least one of:
a substrate material; and
a glass material.

14. The photovoltaic module of claim 5, wherein the first and second external conductors are connected to the first and second internal conductors, respectively, using a first and second connector.

15. The photovoltaic module of claim 5, wherein the first and second external conductors are soldered to the first and second internal conductors.

16. A method for manufacturing a photovoltaic module, the method comprising:
providing a back plate of the photovoltaic module, the back plate comprising a back plate opening;
providing a conductor interface, the conductor interface configured to receive an external conductor; and
fastening the conductor interface to the back plate using an adhesive element, the adhesive element providing at least two points of support for the received external conductor.

17. The method of claim 16, wherein the back plate opening exposes an internal conductor electrically connected to an interior of the photovoltaic module, the method further comprising:
providing an external conductor; and
electrically connecting the external conductor to the internal conductor within the conductor interface.

18. The method of claim 17, wherein the back plate opening further exposes a second internal conductor electrically connected to the interior of the photovoltaic module, the method further comprising:
providing a second external conductor; and
electrically connecting the second external conductor to the second internal conductor within the conductor interface,
wherein the adhesive element provides at least two points of support for the second external conductor.

19. The method of claim 16, the step of fastening an adhesive element further comprising applying the adhesive element to a portion of the back plate corresponding to the back plate opening.

20. The method of claim 17, wherein the conductor interface comprises a base portion and a cap portion, the act of providing a conductor interface further comprising:
fastening the base portion of the conductor interface to the back plate of the photovoltaic module;
electrically connecting the external conductor to the internal conductor within the base portion of the conductor interface; and
after electrically connecting the external conductor to the internal conductor, affixing the cap portion of the conductor interface to the base portion, such that the external conductor traverses an access hole in the conductor interface.

21. The method of claim 17, further comprising:
filling an interior volume of the conductor interface with potting material, wherein the adhesive element allows the potting material to substantially encompass the external conductor.

22. The method of claim 16, wherein the adhesive element further comprises at least one prefabricated opening.

23. The method of claim 22, wherein the at least one prefabricated opening comprises a first opening and a second opening in the adhesive element, wherein a portion of the adhesive element formed between the first opening and the second opening provides a first point of support for the received external conductor, and a portion of the adhesive element formed between the second opening and an outer perimeter of the adhesive element provides a second point of support for the received external conductor.

24. The method of claim 22, wherein the at least one prefabricated opening comprises a first opening in the adhesive element, wherein a portion of the adhesive element extending into the first opening provides a first point of support for the external conductor, and a portion of the adhesive element formed between the first opening and an outer perimeter of the adhesive element provides a second point of support for the external conductor.

25. The method of claim 22, wherein the at least one prefabricated opening comprises a first opening in the adhesive element, wherein a separate supporting within the first opening provides a first point of support for the external conductor, and a portion of the adhesive element formed between the first opening and an outer perimeter of the adhesive element provides a second point of support for the external conductor.

26. An adhesive element for use in manufacturing a photovoltaic module, the adhesive element comprising:
an adhesive coating on a top side and a bottom side of the adhesive element;
a first perforation arranged to form a first point of support and a second point of support for a first wire of the photovoltaic module from the adhesive element; and
a second perforation arranged to form a third point of support and a fourth point of support for a second wire of the photovoltaic module from the adhesive element.

27. The adhesive element of claim 26, wherein the first perforation is arranged to correspond to an eventual centerline of the first wire, and the second perforation is arranged to correspond to an eventual centerline of the second wire.

28. The adhesive element of claim 26, wherein the first perforation comprises a first and a second opening.

29. The adhesive element of claim 26, wherein the second perforation comprises a third and a fourth opening.

30. The adhesive element of claim 28, wherein the first opening is located along a lengthwise centerline of the adhesive element and the second opening is located between the first opening and a perimeter of the adhesive element.

31. The adhesive element of claim 29, wherein the third opening is located along a lengthwise centerline of the adhesive element and the fourth opening is located between the third opening and a perimeter of the element.

32. The adhesive element of claim 26, wherein the first perforation comprises a first opening with a portion of the adhesive element extending into the first opening.

33. The adhesive element of claim 26, wherein the second perforation comprises a second opening with a portion of the adhesive element extending into the second opening.

34. The adhesive element of claim 26, wherein the first perforation comprises a first opening with a detached portion of the adhesive element arranged in the first opening.

35. The adhesive element of claim 26, wherein the second perforation comprises a second opening with a detached portion of the adhesive element arranged in the second opening.

36. The adhesive element of claim 26, the adhesive element further comprising a foam layer between the adhesive coating on the top and bottom side of the adhesive element.

37. The adhesive element of claim 36, wherein the foam layer is acrylic foam.

38. The adhesive element of claim 26, wherein the adhesive element is provided on a roll including a plurality of adhesive elements.

39. The adhesive element of claim 26, wherein the adhesive element has a perimeter configured to accommodate a conductor interface of the photovoltaic module.

40. The adhesive element of claim 26, wherein the adhesive coating is acrylic adhesive.

41. The adhesive element of claim 26, wherein the first and second wires extend from an interior of the photovoltaic module to an exterior of the photovoltaic module.
